(19) United States
(12) Patent Application Publication
(10) Pub. No.: US 2011/0294249 A1
(43) Pub. Date: Dec. 1, 2011

(54) METHOD FOR CLEANING A SUBSTRATE OF SOLAR CELL

(76) Inventor: Seung-Yeop Myong, Seoul (KR)

(21) Appl. No.: 13/118,041

(22) Filed: May 27, 2011

(30) Foreign Application Priority Data
May 31, 2010 (KR) 10-2010-0050959

(51) Int. Cl. H01L 31/0236; H01L 31/18

(52) U.S. Cl. 438/71; 156/345.1; 438/72; 257/E31.13

(57) ABSTRACT

Disclosed is a method for cleaning the substrate of a solar cell. The method includes: providing a single or poly crystalline substrate; performing a wet etching process such that the surface of the substrate is textured; performing an atmospheric pressure plasma cleaning process on the textured substrate; and forming p-n junction.

This application claims priority under 35 U.S.C. §119 to Korean Patent Application No. 10-2010-0050959 filed on May 31, 2010, the entirety of which is hereby incorporated by reference.

### FIELD OF THE INVENTION

The present invention relates to a method for cleaning the substrate of a solar cell and a solar cell manufacturing system therefor.

### BACKGROUND OF THE INVENTION

Recently, as existing energy resources like oil and coal and the like are expected to be exhausted, much attention is increasingly paid to, alternative energy sources which can be used in place of the existing energy sources. As an alternative energy source, sunlight energy is abundant and has no environmental pollution. Therefore, more and more attention is paid to the sunlight energy.

A photovoltaic device is a solar cell that directly converts sunlight energy into electrical energy. The photovoltaic device mainly uses photovoltaic effect of semiconductor junction. In other words, when light is incident on and absorbed by a semiconductor p-n junction doped with p-type impurity and n-type impurity respectively, light energy generates electrons and holes within the semiconductor and the electrons and the holes are separated from each other by an internal electric field. As a result, a photo-electro motive force is generated between both ends of the p-n junction. Here, when electrodes are formed at both ends of the junction and connected with wires, electric current flows externally through the electrodes and the wires.

In order that the existing energy sources such as oil is substituted with the sunlight energy source, it is necessary to provide a photovoltaic device with high photovoltaic conversion efficiency.

### SUMMARY OF THE INVENTION

One aspect of the present invention is a method for cleaning the substrate of a solar cell. The method includes: providing a single or poly crystalline substrate; performing a wet etching process such that the surface of the substrate is, textured; performing an atmospheric pressure plasma cleaning process on the textured substrate; and forming p-n junction.

Another aspect of the present invention is a system for manufacturing the solar cell. The system includes: a first process chamber performing a wet etching such that the surface of a single or poly crystalline substrate is textured; an atmospheric pressure plasma cleaning device for cleaning the textured substrate; and a second process chamber forming p-n junction with respect to the substrate cleaned by the atmospheric pressure plasma cleaning device.

### BRIEF DESCRIPTION OF THE DRAWINGS

FIGS. 1a to 1g show how to clean a substrate of a solar cell in accordance with an embodiment of the present invention.

FIG. 2 shows an example of an atmospheric pressure plasma cleaner used in an embodiment of the present invention.

FIGS. 3a to 3d show a process of forming a p-n junction after cleaning the substrate in accordance with an embodiment of the present invention.

### DETAILED DESCRIPTION

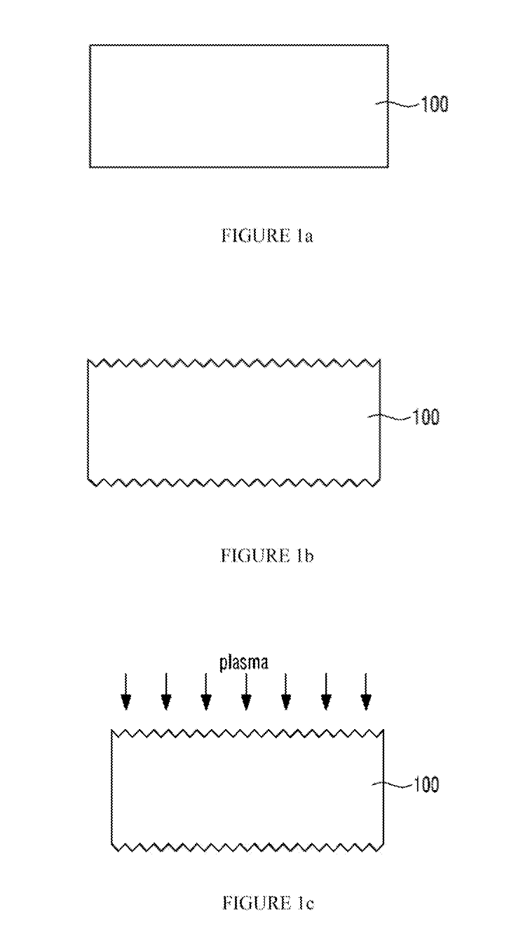

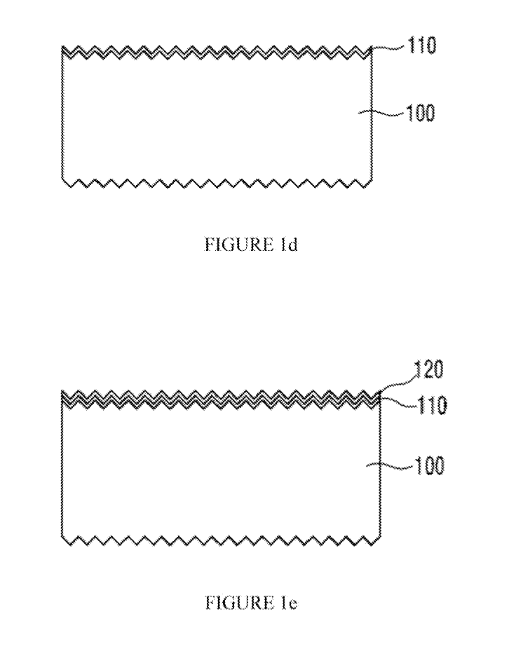

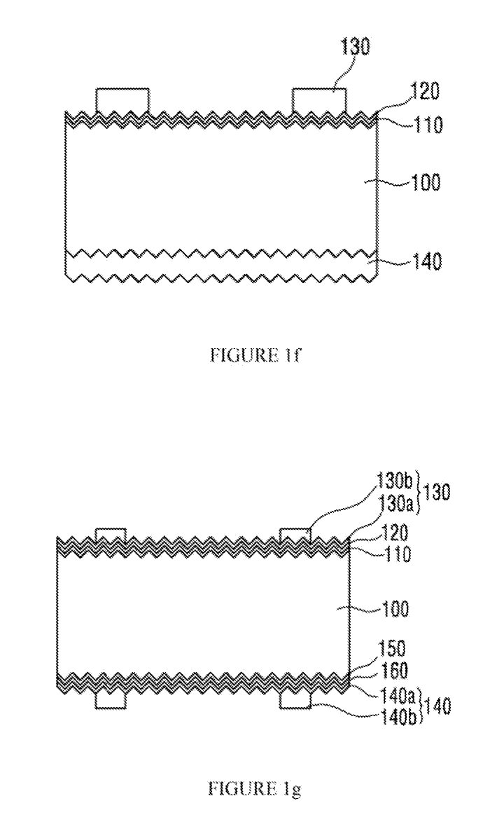

An embodiment of the present invention will be described in detail with reference to the drawings. FIGS. 1a to 1g show how to clean a substrate of a solar cell in accordance with an embodiment of the present invention.

As shown in FIG. 1a, a single crystalline substrate 100 or a poly crystalline substrate 100 is provided.

As shown in FIG. 1b, the surface of the substrate 100 is textured by means of a wet etching process. In order to reduce the amount of reflected light by scattering sunlight incident on the surface of a substrate 100, a texturing process is performed on the surface of the substrate 100, so that the surface of the substrate 100 is textured. The texturing process is performed by means of a wet etching process that makes use of an alkaline solution such as KOH or NaOH, or an acid solution such as HNO₃ or HF.

After the wet etching process is performed on the surface of the substrate 100 in order to form the texturing structure, moisture or organic material may remain on the surface of the substrate 100. The moisture or organic material remaining on the substrate 100 may reduce passivation effect and has a bad influence on the short-circuit current density (Jsc), open circuit voltage (Voc) and a fill factor (FF) of the solar cell.

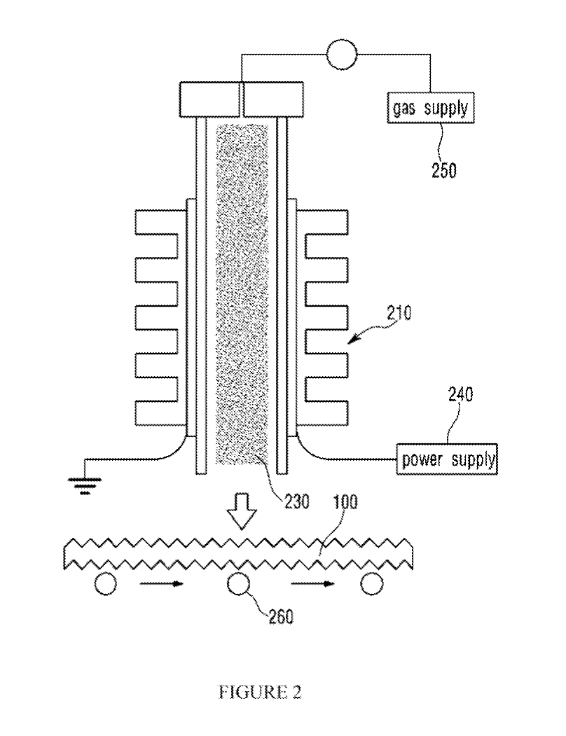

As shown in FIG. 1c, for the purpose of removing the moisture or organic material, an atmospheric pressure plasma cleaning process is performed on the textured substrate 100. FIG. 2 shows an example of an atmospheric pressure plasma cleaning device used in the embodiment of the present invention. The embodiment of the present invention is not limited only to use the atmospheric pressure plasma cleaning device of FIG. 2.

As shown in FIG. 2, oxygen radicals 230 generated from plasma reaction is injected to the textured surface of the substrate 100 by a plasma generator 210 of the atmospheric pressure plasma cleaning device. A power supply 240 applies an alternating voltage to the plasma generator 210. A gas supply apparatus 250 provides gases such as nitrogen, oxygen and air and the like to the plasma generator 210 through a gas pipeline connected to the plasma generator 210. A voltage difference is generated between both electrodes of the plasma generator 210 by the operation of the power supply 240, and then gas plasma is generated by the voltage difference.

Here, photons, excited atoms and molecules, electrons and ions of the plasma may have energy or may be in an excitation energy state of several or several tens of electron volts. Since the excitation energy, is much greater than the binding energy of the etching solution remaining on the surface of the substrate 100, the textured surface of the substrate 100 can be cleaned by means of plasma.

A transfer device 260 transfers the textured substrate 100 at a certain speed during the process of the atmospheric pressure plasma discharge by the plasma generator 210.

A conventional RCA cleaning process uses chemicals such as NH₄OH and H₂O₂ and is complex in that the NH₄OH is heated and then the NH₄OH and H₂O₂ are mixed and the like. Therefore, the productivity of the solar cell is reduced and an incidental cost for chemical treatment and waste water treatment is increased.

Contrarily, in the atmospheric pressure plasma cleaning process used in the embodiment of the present invention, the surface of the substrate 100 is cleaned by generating the plasma at atmospheric pressure. Therefore, the atmospheric pressure plasma cleaning can be performed with no use of the chemicals at atmospheric pressure instead of vacuum.

Since the atmospheric pressure plasma cleaning process is performed at atmospheric pressure, the atmospheric pressure plasma cleaning process can be performed during the transfer of the substrate without loading the substrate in a vacuum chamber. Therefore, the manufacturing time of the solar cell can be reduced.

Meanwhile, rinsing process using deionized water may be performed on the textured substrate 100 prior to the atmospheric pressure plasma cleaning process.

In the embodiment of the present invention, prior to or posterior to performing the atmospheric pressure plasma cleaning process, excimer ultraviolet cleaning process can be performed. The excimer ultraviolet cleaning process intends to remove the organic material remaining on the surface of the substrate 100 after the wet etching process. Through not, only the atmospheric pressure plasma cleaning process but the excimer ultraviolet cleaning process, the organic material can be more satisfactorily removed. Here; the wavelength of the excimer ultraviolet may be equal to or greater than 150 nm and equal to or less than 380 nm.

After the atmospheric pressure'plasma cleaning is performed, p-n junction is formed. That is, as shown in FIG. 1d, an intrinsic amorphous silicon layer 110 is formed on the single crystalline substrate 100 or the poly crystalline substrate 100, which has been doped with a first conductive impurity. Here, FIG. 1d shows that the substrate 100 is doped with an n-type impurity. However, the substrate 100 can be also doped with a p-type impurity.

The intrinsic amorphous silicon layer 110 is formed by injecting silane gas and hydrogen gas into a CVD chamber. The intrinsic amorphous silicon layer 110 reduces defect density at an interface between the first conductive impurity-doped substrate 100 and the intrinsic amorphous silicon layer 110, and then prevents the recombination of electrons and holes.

As described up to now, after the wet etching process is performed to form the textured substrate, the atmospheric pressure plasma cleaning is performed on the substrate 100. As a result, the moisture or organic material remaining on the surface of the substrate 100 through the wet etching process is removed, so that the passivation effect by the intrinsic amorphous silicon layer 110 can be increased.

As shown in FIG. 1e, an amorphous silicon layer 120 doped with a second conductive impurity is formed on the intrinsic amorphous silicon layer 110. To this end, silane gas, hydrogen gas and impurity gas can be injected into the CVD chamber. The amorphous silicon layer 120 doped with the second conductive impurity forms an electric field. When the substrate 100 shown in FIG. 1e is doped with an n-type impurity, the second conductive impurity is a p-type impurity. When the substrate 100 is doped with a p-type impurity, the second conductive impurity is an n-type impurity.

As shown in FIG. 1f, a first electrode 130 is formed in such a manner as to contact with the second conductive impurity-doped amorphous silicon layer 120. A second electrode 140 is formed on the opposite side to the first electrode 130.

In the embodiment of the present invention, the second electrode 140 contacts with the substrate 100. However, for the purpose of passivation of the substrate 100, the intrinsic amorphous silicon layer and the amorphous silicon layer doped with an impurity may be formed between the second electrode 140′ and the substrate 100. That is as shown in FIG. 1g, an intrinsic amorphous silicon layer 150 between the second electrode 140 and the substrate 100 increases the passivation effect at the interface between the substrate 100 and the intrinsic amorphous silicon layer. An amorphous silicon layer 160 doped with the impurity forms a back surface field (BSF). The first electrode 130 may include a transparent conductive oxide layer 130a such as ZnO or indium tin oxide (ITO), and a collector electrode 130b formed on the transparent conductive oxide layer 130a. The second electrode 140 may also include a transparent conductive oxide layer 140a and a collector electrode 140b formed on the transparent conductive oxide layer 140a. The transparent conductive oxide layers 130a and 140a can be formed by a sputtering method. The collector electrodes 130b and 140b can be formed by a screen printing method. The transparent conductive oxide layers 130a and 140a have resistances greater than those of the collector electrodes 130b and 140b. So the collector electrodes 130b and 140b help the generated electric current flow easily.

In the foregoing, the atmospheric pressure plasma cleaning is performed, and then the p-n junction is formed by the first conductive impurity doped substrate 100 and the second conductive impurity doped amorphous silicon layer 120.

In the following description, the atmospheric pressure plasma cleaning is performed, and then the p-n junction is formed on the substrate 100 by the first and the second conductive impurities doped in the substrate.

Through the processes explained referring to FIGS. 1a to 1c the textured substrate is formed and the atmospheric pressure plasma cleaning is performed. Prior to or posterior to performing the atmospheric pressure plasma cleaning, excimer ultraviolet cleaning is performed.

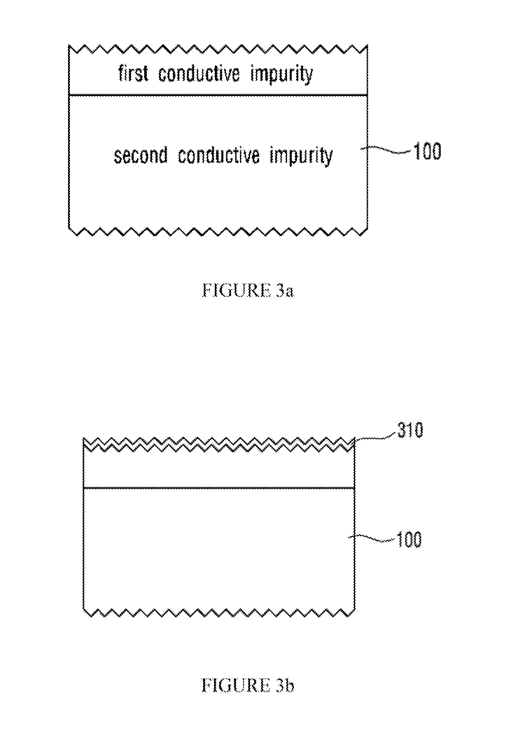

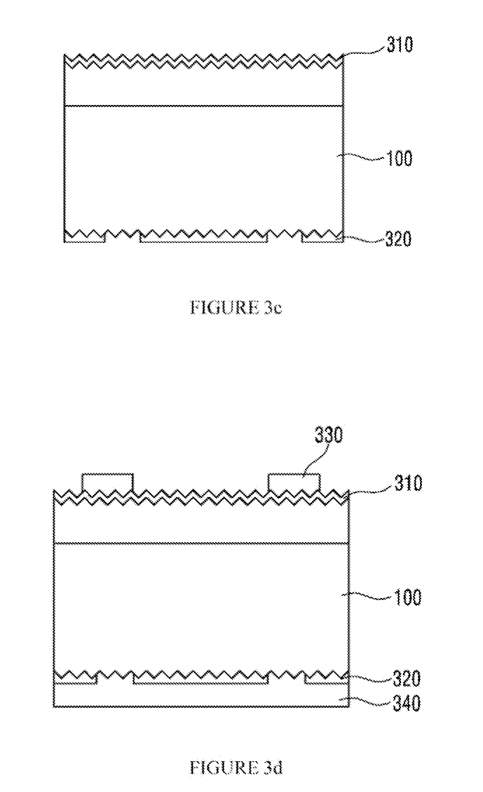

As shown in FIG. 3a, a second conductive impurity is doped in the single or poly crystalline substrate 100 doped with a first conductive impurity. Here, when the first conductive impurity is a p-type impurity like group III element, the second conductive impurity is an n-type impurity like group V element. When the first conductive impurity is an n-type impurity like group V element, the second conductive impurity is a p-type impurity like group III element. As such, the p-type impurity and the n-type impurity are doped in the single crystalline substrate 100 or the poly crystalline substrate 100, so that p-n junction is formed on the substrate 100.

The second conductive impurity is doped by diffusing the second conductive impurity at a temperature of about 1000°. The second conductive impurity can be diffused by using a vapor diffusion method, a coating diffusion method or an ion implantation method and the like.

Not only the doping methods mentioned above but a plasma doping method or a laser doping method can be also used. The plasma doping method is performed as follows. A sample to be ion-implanted is directly placed in a plasma chamber of about 200°. A voltage that is relatively higher or lower than that of the grounded wall of the vacuum chamber is repetitiously applied to the sample. Therefore, while a high voltage pulse is applied to the sample, a plasma sheath is formed around the sample, so that ions having energy of the applied voltage are implanted into the substrate 100.

The laser doping method is performed as follows. After a dopant layer including impurities is deposited on the substrate 100, energy of laser pulse is absorbed as thermal energy at an interface between the deposited dopant layer and the substrate 100. Therefore, the surface portion of the substrate 100 is molten and, at this time, the impurities are diffused.

As described above, a doping process is performed at a high temperature. Therefore, when the substrate 100 is not fully cleaned, a furnace for the doping process or the inside of the chamber can be polluted, so that the p-n junction may not be stably formed. In the embodiment of the present invention, since the atmospheric pressure plasma cleaning is performed prior to the doping process at a high temperature, the p-n junction can be stably formed at the time of, performing the doping process.

As shown, in FIG. 3b, an anti-reflective layer 310 is formed on the substrate 100. The anti-reflective layer 310 may include amorphous silicon or silicon alloy. For example, the anti-reflective layer 310 includes SiOx or SiNx. Such an anti-reflective layer 310 is formed by a plasma-enhanced chemical vapor deposition (PECVD) process.

As shown in FIG. 3c, a passivation layer 320 is formed on a surface opposite to the surface of the substrate 100 on which the anti-reflective layer 310 has been formed. The hydrogen of the passivation layer 320 is bonded to dangling bonds at an interface between the substrate 100 and the passivation layer 320 and prevents the recombination of carriers. Such a passivation layer 320 can be also formed by using the PECVD process.

As shown in FIG. 3d, a first electrode 330 and a second electrode 340 are formed in such a manner as to contact with the both sides of the substrate 100 respectively. For example, the first electrode 330 is formed contacting with the surface of the substrate 100 in which the second conductive impurity has been diffused, and the second electrode 340 is formed contacting with the surface of the substrate 100 on which the passivation layer 320 has been formed. The first electrode 330 and the second electrode 340 can be formed by using a sputtering process, a chemical vapor deposition (CVD) process or a screen printing process.

Though the embodiment of the present invention shows the first electrode 330 is formed after the anti-reflective layer 310 is formed, the anti-reflective layer 310 can be formed after the first electrode 330 is formed contacting with the surface of the substrate 100 in which the second conductive impurity has been diffused. For example, after the anti reflective layer 310 is formed, the first electrode 330 is formed on the anti-reflective layer 310 by means of a screen printing process. Subsequently, through a firing process, the first electrode 330 can penetrate the anti-reflective layer 310 and contact with the substrate 100.

As described above, at least one of the atmospheric pressure plasma cleaning process and the excimer ultraviolet cleaning process can be performed before the passivation layer 320 is formed. Since such a cleaning process removes the contaminants, it is possible to reduce the influence of the contaminants at the time of forming the passivation layer 320.

Additionally, at least one of the atmospheric pressure plasma cleaning process and the excimer ultraviolet cleaning process can be performed before at least one of the first electrode 330 and the second electrode 340 is formed. Since such a cleaning process removes the contaminants, it is possible to reduce the influence of the contaminants at the time of forming the electrode.

Meanwhile, when there is a long time interval between a solar cell formation process and a solar cell module process, the atmospheric pressure plasma cleaning may be performed before the module process is performed.

The following description will focus on a solar cell manufacturing system, which can perform the aforementioned method for cleaning the solar cell.

The solar cell manufacturing system according to the embodiment of the present invention may include a first process chamber performing the wet etching so as to form a textured surface of the single crystalline substrate or the poly crystalline substrate, the atmospheric pressure plasma cleaning device for cleaning the textured substrate, and a second process chamber forming the p-n junction with respect to the substrate cleaned by the atmospheric pressure plasma cleaning device.

The solar cell manufacturing system according to the embodiment of the present invention may further include an excimer ultraviolet cleaning device that cleans the substrate before or after the atmospheric pressure plasma cleaning device cleans the substrate.

When the substrate is doped with the first conductive impurity, the intrinsic amorphous silicon layer may be formed on the substrate in the second process chamber, and the amorphous silicon layer doped with the second conductive impurity may be formed on the intrinsic amorphous silicon layer in the second process chamber.

When the substrate is doped with the first conductive impurity, the second conductive impurity may be doped in the substrate in the second process chamber.

The solar cell manufacturing system according to the embodiment of the present invention may further include a third process chamber and/or a fourth process chamber. The third process chamber is used to form the anti-reflective layer on the substrate on which the p-n junction has been formed. The fourth process chamber is used to form the passivation layer on a surface opposite to the surface of substrate on which the anti-reflective layer has been formed.

Before the passivation layer is formed in the fourth process chamber, the atmospheric pressure plasma cleaning device may clean the surface of the substrate on which the passivation layer is to be formed.

The solar cell manufacturing system according to the embodiment of the present invention may further include an excimer ultraviolet cleaning device. Before the passivation layer is formed in the fourth process chamber, the excimer ultraviolet cleaning device may clean the surface of the substrate on which the passivation layer is to be formed.

The solar cell manufacturing system according to the embodiment of the present invention may further include a fifth process chamber used to form the first electrode and/or the second electrode on both sides of the substrate in which the p-n junction has been formed.

Before at least one of the first electrode and the second electrode is formed in the fifth process chamber, the atmospheric pressure plasma cleaning device may clean the substrate.

Before at least one of the first electrode and the second electrode is formed in the fifth process chamber, the excimer ultraviolet cleaning device may clean the substrate.

The configurations and functions of the atmospheric pressure plasma cleaning device, the excimer ultraviolet cleaning device and the first to the fifth process chambers are the same as those of the method for cleaning the solar cell. Therefore, the detailed description thereof will be omitted. Additionally, the configurations are described in a singular manner, a plurality of the atmospheric pressure plasma cleaning devices, the excimer ultraviolet cleaning devices and the first to the fifth process chambers are also included.

While the embodiment of the present invention has been described with reference to the accompanying drawings, it can be understood by those skilled in the art that the present invention can be embodied in other specific forms without departing from its spirit or essential characteristics. Therefore, the foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A method for cleaning a substrate of a solar cell, the method comprising:
providing a single or poly crystalline substrate;
performing a wet etching process such that the surface of the substrate, is textured;
performing an atmospheric pressure plasma cleaning process on the textured substrate; and
forming p-n junction with respect to the substrate cleaned by the atmospheric pressure plasma cleaning device.

2. The method of claim 1, wherein the atmospheric pressure plasma cleaning is performed during the transfer of the substrate.

3. The method of claim 1, wherein an excimer ultraviolet cleaning process is performed prior to or posterior to performing the atmospheric pressure plasma cleaning process.

4. The method of claim 1, wherein, when the substrate is doped with a first conductive impurity, the forming the p-n junction comprises:
forming an intrinsic amorphous silicon layer on the substrate; and
forming an amorphous silicon layer doped with a second conductive impurity on the intrinsic amorphous silicon layer.

5. The method of claim 1, wherein the forming the p-n junction is performed by doping a second conductive impurity in the substrate doped with a first conductive impurity.

6. The method of claim 5, further comprising:
forming an anti-reflective layer on the substrate; and
forming a passivation layer on a surface opposite to the surface of the substrate on which the anti-reflection layer is formed.

7. The method of claim 6, wherein at least one of an atmospheric pressure plasma cleaning process and an excimer ultraviolet cleaning process is performed before, the passivation layer is formed.

8. The method of claim 5, wherein a first electrode and a second electrode are formed contacting with the both surfaces of the substrate respectively, and at least one of an atmospheric pressure plasma cleaning process and an excimer ultraviolet cleaning process is performed before at least one of the first electrode and the second electrode is formed.

9. A solar cell manufacturing system comprising:
a first process chamber performing a wet etching such that the surface of a single or poly crystalline substrate is textured;
an atmospheric pressure plasma cleaning, device for cleaning the textured substrate; and
a second process chamber forming p-n junction with respect to the substrate cleaned by the atmospheric pressure plasma cleaning device.

10. The system of claim 9, wherein the atmospheric pressure plasma cleaning device comprises:
a plasma generator that injects oxygen radicals to the textured substrate;
a power supply that applies an alternating voltage to the plasma generator; and
a gas supply apparatus that supplies gases to the plasma generator through a gas pipeline connected to the plasma generator.

11. The system of claim 9, wherein the atmospheric pressure plasma cleaning device cleans the substrate during the transfer of the substrate.

12. The system of claim 9, further comprising an excimer ultraviolet cleaning device that cleans the substrate before or after the atmospheric pressure plasma cleaning device cleans the textured substrate.

13. The system of claim 9, wherein the substrate is doped with a first conductive impurity, an intrinsic amorphous silicon layer is formed on the substrate and an amorphous silicon layer doped with a second conductive impurity is formed on the intrinsic amorphous silicon layer in the second process chamber.

14. The system of claim 9, wherein the substrate is doped with a first conductive impurity, and a second conductive impurity is doped in the substrate in the second process chamber.

15. The system of claim 14, further comprising:
a third process chamber forming an anti-reflection layer on the substrate on which the p-n junction is formed; and
a fourth process chamber forming a passivation layer on a surface opposite to the surface of substrate on which the anti-reflective layer is formed.

16. The system of claim 15, wherein, before the passivation layer is formed in the fourth process chamber, the atmospheric pressure plasma cleaning device cleans the surface of the substrate on which the passivation layer is to be formed.

17. The system of claim 15, further comprising an excimer ultraviolet cleaning device, wherein, before the passivation layer is formed in the fourth process chamber, the excimer ultraviolet cleaning device cleans the surface of the substrate on which the passivation layer is to be formed.

18. The system of claim 14, further comprising a fifth process chamber forming a first electrode and a second electrode on both surface of the substrate in which the p-n junction is formed.

19. The system of claim 18, wherein, before at least one of the first electrode and the second electrode is formed in the fifth process chamber, the atmospheric pressure plasma cleaning device cleans the substrate.

20. The system of claim 18, further comprising an excimer ultraviolet cleaning device, wherein, before at least one of the first electrode and the second electrode is formed in the fifth process chamber, the excimer ultraviolet cleaning device cleans the substrate.
